(19) United States
(12) Patent Application Publication
(10) Pub. No.: US 2026/0150275 A1
(43) Pub. Date: May 28, 2026

(54) SEMICONDUCTOR DEVICE

(71) Applicant: SK hynix Inc., Gyeonggi-do (KR)

(72) Inventors: Dong Soo KIM, Gyeonggi-do (KR); Jung Woo PARK, Gyeonggi-do (KR)

(21) Appl. No.: 19/176,155

(22) Filed: Apr. 11, 2025

(30) Foreign Application Priority Data
Nov. 25, 2024 (KR) 10-2024-0169855

(51) Int. Cl. H10B 12/00

(52) U.S. Cl. CPC H10B 12/50; H10B 12/315

(57) ABSTRACT

A semiconductor device comprising a gate structure disposed on a substrate, a first spacer disposed on the substrate and disposed on two opposite sides of the gate structure, a second spacer disposed on the substrate, outside the first spacer, a semiconductor layer disposed on the substrate and contacting an outer surface of the second spacer, and a third spacer covering an upper surface of the gate structure, a side surface of the second spacer, and an upper surface of the semiconductor layer.

### CROSS-REFERENCES TO RELATED APPLICATION

The present application claims priority under 35 U.S.C. 119(a) to Korean patent application number 10-2024-0169855 filed on Nov. 25, 2024, which is incorporated herein by reference in its entirety.

### TECHNICAL FIELD

Embodiments of the present disclosure relate generally to semiconductor technology, and, more particularly, to a semiconductor device.

### BACKGROUND

By their miniaturization, multi-functionality, and/or low manufacturing cost characteristics, semiconductor memory devices are attracting attention as an important element in the electronics industry. As the electronics industry advances, semiconductor memory devices are becoming increasingly highly integrated. For developing more highly integrated semiconductor memory devices, the width of the lines included in these devices needs to further decrease.

Further, various other elements included in the memory devices, such as transistors, are also being downsized and, to that end, the size of each of the components that make up these elements are also decreasing. However, it is difficult to maintain the performance characteristics of an element while downsizing the components constituting the element. Hence, new improved solutions are needed.

### SUMMARY

Embodiments of the present disclosure provide a semiconductor device capable of preventing deterioration of element characteristics due to process defects.

Embodiments of the present disclosure provide a semiconductor device comprising a gate structure disposed on a substrate, a first spacer disposed on the substrate and disposed on two opposite sides of the gate structure, a second spacer disposed on the substrate, outside the first spacer, and including SiCO, SiCON, SiCOH, or a combination thereof, a semiconductor layer disposed on the substrate and contacting an outer surface of the second spacer, and a third spacer covering an upper surface of the gate structure, a side surface of the second spacer, and an upper surface of the semiconductor layer.

Embodiments of the present disclosure provide a semiconductor device comprising a substrate including a cell area and a peripheral area around the cell area and a peripheral transistor disposed in a peripheral area of the substrate, wherein the peripheral transistor includes a gate structure disposed on the substrate, a plurality of spacers disposed on the substrate, positioned on a side surface of the gate structure, and at least partially including SiCO, SiCON, SiCOH, or a combination thereof, and a semiconductor layer disposed on the substrate and spaced apart from the gate structure in a direction parallel to an upper surface of the substrate.

Embodiments of the present disclosure provide a gate structure disposed on a substrate and spacers covering the sides and top surface of the gate structure, wherein the spacers comprise first, second, third, and fourth spacers, wherein the first and second spacers are disposed on the substrate and on two opposite sides of the gate structure, wherein the third spacer is disposed on the side surface of the second spacer and also over the top surfaces of the first and second spacers and the top surface of the gate structure, and wherein the fourth spacer is disposed between the second and third spacer and does not contact the substrate.

According to embodiments of the present disclosure, it is possible to prevent deterioration of element characteristics of the semiconductor device due to process defects.

### BRIEF DESCRIPTION OF THE DRAWINGS

FIG. 1 is a view illustrating a transistor included in a semiconductor device according to embodiments of the present disclosure;

FIGS. 2 to 4 are views illustrating another transistor included in a semiconductor device according to embodiments of the present disclosure;

FIGS. 5 and 6 are views illustrating a semiconductor device according to embodiments of the present disclosure;

FIGS. 7 to 15 are views illustrating a method for manufacturing a transistor included in a semiconductor device according to embodiments of the present disclosure; and

FIGS. 16 to 21 are views illustrating another method for manufacturing a transistor included in a semiconductor device according to embodiments of the present disclosure.

### DETAILED DESCRIPTION

Hereinafter, various embodiments of the present disclosure will be described in detail with reference to accompanying drawings.

In the accompanying drawings, the three directions parallel to the upper surface of the substrate are defined as a first direction FD, a second direction SD, and a third direction TD, respectively and the direction protruding vertically from the upper surface of the substrate is defined as a fourth direction VD. The first direction FD and the second direction SD may be substantially perpendicular to each other. The fourth direction VD is a direction perpendicular to the first direction FD, the second direction SD, and the third direction TD. In the following specification, ‘vertical’ or ‘vertical direction’ will be used as having substantially the same meaning as the fourth direction VD. The direction indicated by arrow in the drawings and the opposite direction indicate the same direction.

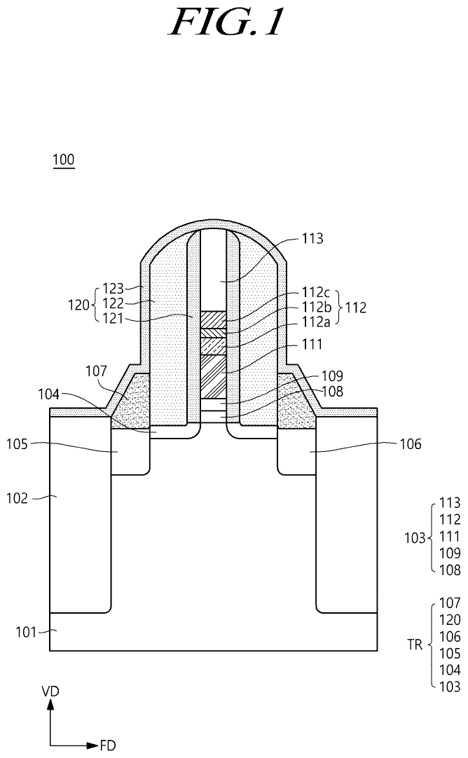

FIG. 1 is a view illustrating a transistor included in a semiconductor device according to embodiments of the present disclosure.

Referring to FIG. 1, a semiconductor device 100 according to an embodiment of the present disclosure includes a substrate 101, an element isolation layer 102, and a first transistor TR.

The substrate 101 may include a semiconductor substrate such as a silicon wafer or a silicon on insulator (SOI) wafer. The substrate 101 may include a group III-V semiconductor substrate, e.g., a compound semiconductor substrate such as gallium arsenide (GaAs). The substrate 101 may include monocrystalline silicon, polysilicon, amorphous silicon, monocrystalline silicon germanium, polycrystalline silicon germanium, carbon-doped silicon, or a combination thereof. In an embodiment, the substrate 101 may be silicon doped with a group III element.

The element isolation layer 102 is disposed in the substrate 101. The element isolation layer 102 may be formed using a trench element isolation technology such as shallow trench isolation (STI).

The element isolation layer 102 may include a single layer or multiple layers. The element isolation layer 102 may include at least two elements selected from the group consisting of Si, O, N, C, and H. For example, the element isolation layer 102 may include silicon oxide, silicon nitride, silicon oxynitride, low-K dielectrics, high-K dielectrics, or a combination thereof.

The first transistor TR is disposed on the substrate 101. The first transistor TR may be an NMOS (n-channel metal-oxide-semiconductor) or a PMOS (p-channel metal-oxide-semiconductor) transistor. The first transistor TR includes a gate structure 103, an impurity area 104, source/drain areas 105 and 106, a semiconductor layer 107, and spacers 120.

The gate structure 103 is positioned between the source/drain areas 105 and 106 on the substrate 101. The gate structure 103 includes a gate insulation layer 108, a work function adjustment layer 109, a first gate electrode 111, a second gate electrode 112, and a gate capping layer 113.

The gate insulation layer 108 is disposed on the substrate 101. The gate insulation layer 108 may be a single layer or multiple layers. The gate insulation layer 108 may include silicon oxide, silicon nitride, silicon oxynitride, high-K dielectric, or a combination thereof.

The work function adjustment layer 109 is disposed on the gate insulation layer 108. The work function adjustment layer 109 may be a single layer or multiple layers. The work function adjustment layer 109 may be formed of metal, metal nitride, metal carbide, a conductor including metal atoms, or a combination thereof.

The first gate electrode 111 is disposed on the work function adjustment layer 109. The first gate electrode 111 may include a conductive material such as metal, metal nitride, metal silicide, polysilicon, conductive carbon, or a combination thereof. In an embodiment, the first gate electrode 111 may be doped polysilicon.

The second gate electrode 112 is disposed on the first gate electrode 111. The second gate electrode 112 includes barrier layers 112a and 112b and an electrode layer 112c. The barrier layers 112a and 112b and the electrode layer 112c may include a conductive material such as metal, metal nitride, metal silicide, polysilicon, conductive carbon, or a combination thereof. In an embodiment, the barrier layers 112a and 112b may include at least one stacked structure selected from among tungsten nitride (WNx), Tungsten Silicon Nitride (WSiN), Tantalum/Titanium Nitride (Ta/TiN), Titanium/Titanium Nitride (Ti/TiN), Magnesium/Titanium Nitride (Mg/TiN), and Strontium/Titanium Nitride (Sr/TiN). In an embodiment, the electrode layer 112c may include W, Mo, Au, Cu, Al, Ni, or Co.

The gate capping layer 113 is disposed on the second gate electrode 112. In an embodiment, the gate capping layer 113 may include silicon nitride.

The source/drain areas 105 and 106 are disposed in the substrate 101. In an embodiment, the source/drain areas 105 and 106 may include monocrystalline silicon having N-type impurities. The N-type impurities may include P, As, or a combination thereof.

The impurity area 104 is positioned between the source/drain areas 105 and 106. The impurity area 104 is an area doped with impurities and may include impurities having a higher concentration than the substrate 101. In an embodiment, the impurity area 104 may include a lightly doped drain (LDD) area and a halo doped area. The halo doped area involves a higher concentration of dopants.

The spacers 120 are disposed on the side surface of the gate structure 103. The spacers 120 include a first spacer 121, a second spacer 122, and a third spacer 123.

The first spacer 121 is disposed on the side surface of the gate structure 103. The first spacer 121 contacts the side surface of the gate structure 103. In an embodiment, the first spacer 121 may cover the entire side surface of the gate structure 103. The lower surface of the first spacer 121 contacts the upper surface of the substrate 101. The lower surface of the first spacer 121 may contact the impurity area 104 in the substrate 101. The first spacer 121 may include silicon nitride, silicon carbide, silicon oxide, or a combination thereof. In an embodiment, the first spacer 121 may be silicon nitride. In another embodiment, the first spacer 121 may include silicon oxycarbide (SiCO), silicon oxycarbonitride (SiCON), silicon oxycarbohydride (SiCOH), or a combination thereof.

The second spacer 122 is disposed on the outer surface of the first spacer 121. In an embodiment, the second spacer 122 may cover the entire outer surface of the first spacer 121. The second spacer 122 contacts the upper surface of the substrate 101. The lower surface of the second spacer 122 may contact the impurity area 104 in the substrate 101. In an embodiment, the lower surface of the second spacer 122 may be positioned lower than the lower surface of the first spacer 121. The second spacer 122 may include silicon nitride, silicon carbide, silicon oxide, or a combination thereof. In an embodiment, the second spacer 122 may include silicon oxycarbide (SiCO), silicon oxycarbonitride (SiCON), silicon oxycarbohydride (SiCOH), or a combination thereof. The semiconductor layer 107 is disposed on the outer surface of the second spacer 122. The semiconductor layer 107 is disposed on the source/drain areas 105 and 106 of the substrate 101. The semiconductor layer 107 may be positioned higher than the upper surface of the substrate 101. The semiconductor layer 107 may be an epitaxial layer formed using a method such as selective epitaxial growth (SEG). The semiconductor layer 107 may be a material layer capable of enhancing carrier mobility. In an embodiment, the semiconductor layer 107 may include silicon germanium.

The third spacer 123 is disposed on the semiconductor layer 107, the second spacer 122, and the gate structure 103. The third spacer 123 may cover the upper surface of the semiconductor layer 107, the side surface and the upper surface of the second spacer 122, and the upper surface of the gate structure 103. Referring to FIG. 1 the upper surface of the gate structure 103 may consist of the top surface of the gate capping layer 113. 1 An inner side surface of the third spacer 123 may contact the second spacer 122. The third spacer 123 may include silicon nitride, silicon carbide, silicon oxide, or a combination thereof. In an embodiment, the third spacer 123 may be silicon nitride.

In an embodiment, the second spacer 122 may include a material having a dielectric constant less than that of the material forming the first spacer 121. For example, the first spacer 121 may include silicon nitride, and the second spacer 122 may include silicon oxycarbide (SiCO), silicon oxycarbonitride (SiCON), silicon oxycarbohydride (SiCOH), or a combination thereof.

In another embodiment, the second spacer 122 may include the same material as the material forming the first spacer 121. In the above-described embodiment, the first spacer 121 and the second spacer 122 may include SiCO, SiCON, SiCOH, or a combination thereof.

In an embodiment, the third spacer 123 may include the same material as the material forming the first spacer 121. For example, the first spacer 121 and the third spacer 123 may include silicon nitride.

In an embodiment, the first spacer 121 may include silicon nitride, the second spacer 122 may include SiCO, SiCON, SiCOH, or a combination thereof, and the third spacer 123 may include silicon nitride.

In another embodiment, the first spacer 121 and the second spacer 122 may include SiCO, SiCON, SiCOH, or a combination thereof, and the third spacer 123 may include silicon nitride.

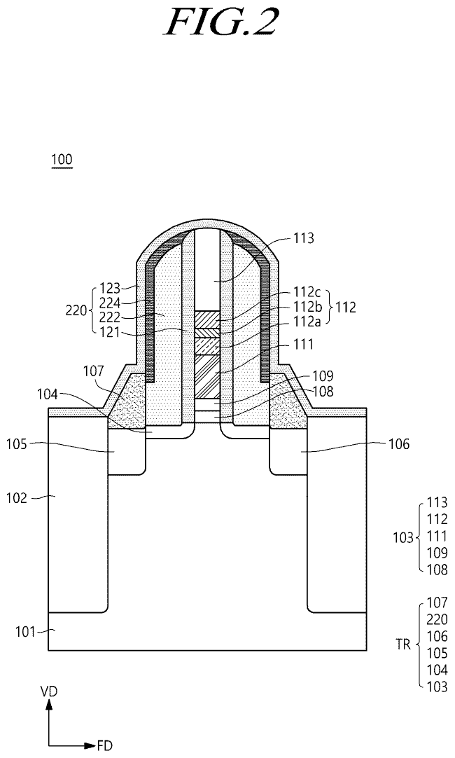

FIGS. 2 to 4 are views illustrating another transistor included in a semiconductor device according to embodiments of the present disclosure.

Referring to FIG. 2, a semiconductor device 100 according to an embodiment includes a substrate 101, an element isolation layer 102, and a first transistor TR.

The first transistor TR may include a gate structure 103, an impurity area 104, source/drain areas 105 and 106, a semiconductor layer 107, and spacers 220.

The spacers 220 include a first spacer 121, a second spacer 222, a third spacer 123, and a fourth spacer 224.

The first spacer 121 is disposed on the side surface of the gate structure 103. The first spacer 121 contacts the side surface of the gate structure 103. In an embodiment, the first spacer 121 may cover the entire side surface of the gate structure 103. The lower surface of the first spacer 121 contacts the upper surface of the substrate 101. The lower surface of the first spacer 121 may contact the impurity area 104 in the substrate 101. The first spacer 121 may include silicon nitride, silicon carbide, silicon oxide, or a combination thereof. In an embodiment, the first spacer 121 may be silicon nitride.

The second spacer 222 is disposed on the outer surface of the first spacer 121. In an embodiment, the upper surface of the second spacer 222 may be positioned at a height lower than the upper surface of the first spacer 121. The outer surface and the upper surface of the second spacer 222 contact the fourth spacer 224. The lower surface of the second spacer 222 may contact the impurity area 104 in the substrate 101. In an embodiment, the lower surface of the second spacer 222 may be positioned lower than the lower surface of the first spacer 121. The second spacer 222 may include silicon nitride, silicon carbide, silicon oxide, or a combination thereof. In an embodiment, the second spacer 222 may include SiCO, SiCON, SiCOH, or a combination thereof.

The semiconductor layer 107 may be disposed on the outer surface of the second spacer 222. More specifically, the semiconductor layer 107 may be disposed only on a lower portion of the outer surface of the second spacer 222. A remaining portion of the outer surface of the second spacer 222 may be covered by the fourth spacer 224. The semiconductor layer 107 may also be disposed on the source/drain areas 105 and 106 of the substrate 101. More specifically, a lower surface of the semiconductor layer 107 (also referred to as the bottom surface of the semiconductor layer 107) may be disposed on the source drain areas 105 and 106 of the substrate 101. The semiconductor layer 107 may be positioned higher than the upper surface of the substrate 101. At least an uppermost portion of an inner surface of the semiconductor layer 107 may contact a lowermost portion of the outer surface of the fourth spacer 224.

In an embodiment, The semiconductor layer 107 may have an outer side surface that consists of a vertical lower portion and an inclined upper portion. The top surface of the semiconductor layer 107 may be much smaller than the bottom surface of the semiconductor layer 107 in the first direction FD as shown in FIG. 2.

The third spacer 123 is disposed on the semiconductor layer 107, the fourth spacer 224, and the gate structure 103. The third spacer 123 may cover the upper surface of the semiconductor layer 107, the inclined portion of the side surface of the semiconductor layer 107, the upper surface of the fourth spacer 224, the outer side surface of the fourth spacer 224 that is not covered by the semiconductor layer 107, and the upper surface of the gate structure 103. The inner side surface of the third spacer 123 may contact the fourth spacer 224. The third spacer 123 may include silicon nitride, silicon carbide, silicon oxide, or a combination thereof. In an embodiment, the third spacer 123 may be silicon nitride.

The fourth spacer 224 is disposed between the second spacer 222 and the third spacer 123. In an embodiment, the fourth spacer 224 may be a layer formed by oxidizing the surface of the second spacer 222. The outer surface of the fourth spacer 224 contacts the third spacer 123. At least a portion of the outer surface of the fourth spacer 224 may contact the semiconductor layer 107. The lower surface of the fourth spacer 224 may be spaced apart from the substrate 101 in the vertical direction. In an embodiment, the fourth spacer 224 may include silicon oxide.

In an embodiment, the second spacer 222 may include a material having a dielectric constant less than that of the material forming the first spacer 121. For example, the first spacer 121 may include silicon nitride, and the second spacer 222 may include SiCO, SiCON, SiCOH, or a combination thereof.

In an embodiment, the fourth spacer 224 may include a material having a dielectric constant less than that of the material forming the second spacer 222. For example, the fourth spacer 224 may include silicon oxide.

In an embodiment, the first spacer 121 may include silicon nitride, the second spacer 222 may include SiCO, SiCON, SiCOH, or a combination thereof, the third spacer 123 may include silicon nitride, and the fourth spacer 224 may include silicon oxide.

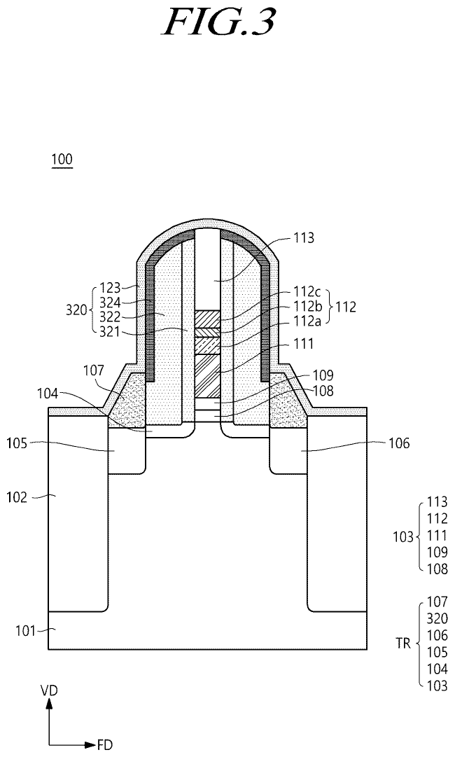

Referring to FIG. 3, a semiconductor device 100 according to an embodiment includes a substrate 101, an element isolation layer 102, and a first transistor TR.

The first transistor TR includes a gate structure 103, an impurity area 104, source/drain areas 105 and 106, a semiconductor layer 107, and spacers 320.

The spacers 220 include a first spacer 321, a second spacer 322, a third spacer 123, and a fourth spacer 324.

The first spacer 321 is disposed on the side surface of the gate structure 103. The first spacer 321 contacts the side surface of the gate structure 103. In an embodiment, the first spacer 321 may expose a portion of the side surface of the gate structure 103. The lower surface of the first spacer 321 may contact the impurity area 104 in the substrate 101. The upper surface of the first spacer 321 may be spaced apart from the third spacer 123. The first spacer 321 may include silicon nitride, silicon carbide, silicon oxide, or a combination thereof. In an embodiment, the first spacer 321 may include SiCO, SiCON, SiCOH, or a combination thereof.

The second spacer 322 is disposed on the outer surface of the first spacer 321. In an embodiment, the upper surface of the second spacer 322 may be positioned at a height lower than the upper surface of the first spacer 321. The outer surface and the upper surface of the second spacer 322 may contact the fourth spacer 324. The lower surface of the second spacer 322 may contact the impurity area 104 in the substrate 101. In an embodiment, the lower surface of the second spacer 322 may be positioned lower than the lower surface of the first spacer 321. The second spacer 322 may include silicon nitride, silicon carbide, silicon oxide, or a combination thereof. In an embodiment, the second spacer 322 may include SiCO, SiCON, SiCOH, or a combination thereof.

The fourth spacer 324 is disposed between the second spacer 322 and the third spacer 123. In an embodiment, the fourth spacer 324 may be a layer formed by oxidizing the surface of the second spacer 322. At least a portion of the outer surface of the fourth spacer 324 may contact the semiconductor layer 107. The lower surface of the fourth spacer 324 may be spaced apart from the substrate 101 in the vertical direction. The fourth spacer 324 may contact the upper surface of the first spacer 321 and the upper surface and the side surface of the second spacer 322. In an embodiment, the fourth spacer 324 may include silicon oxide.

In an embodiment, the second spacer 322 may include the same material as the material forming the first spacer 321. For example, the first spacer 321 and the second spacer 322 may include SiCO, SiCON, SiCOH, or a combination thereof.

In an embodiment, the fourth spacer 324 may include a material having a dielectric constant less than that of the material forming the second spacer 322. For example, the fourth spacer 324 may include silicon oxide.

In an embodiment, the first spacer 321 and the second spacer 322 may include SiCO, SiCON, SiCOH, or a combination thereof, the third spacer 123 may include silicon nitride, and the fourth spacer 324 may include silicon oxide.

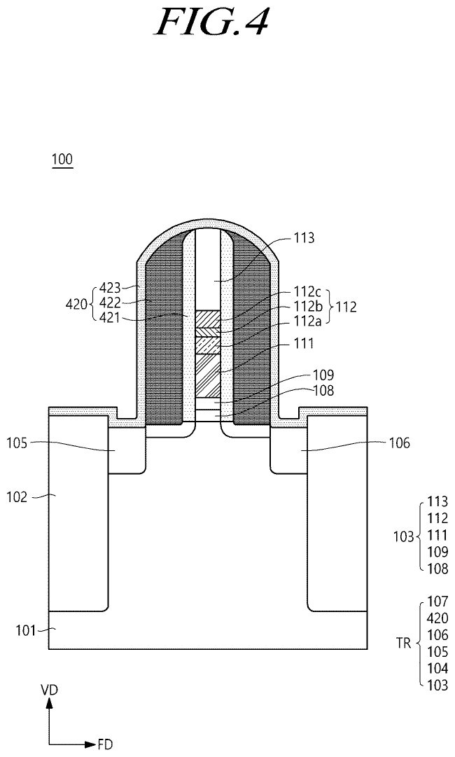

Referring to FIG. 4, a semiconductor device 100 according to an embodiment includes a substrate 101, an element isolation layer 102, and a first transistor TR.

The first transistor TR includes a gate structure 103, an impurity area 104, source/drain areas 105 and 106, and spacers 420.

The spacers 420 include a first spacer 421, a second spacer 422, and a third spacer 423.

The first spacer 421 is disposed on the side surface of the gate structure 103. The first spacer 421 contacts the side surface of the gate structure 103. In an embodiment, the first spacer 421 may cover the entire side surface of the gate structure 103. The lower surface of the first spacer 421 contacts the upper surface of the substrate 101. The lower surface of the first spacer 421 may contact the impurity area 104 in the substrate 101. The first spacer 421 may include silicon nitride, silicon carbide, silicon oxide, or a combination thereof. In an embodiment, the first spacer 421 may include SiCO, SiCON, SiCOH, or a combination thereof.

The second spacer 422 is disposed on the outer surface of the first spacer 421. In an embodiment, the second spacer 422 may cover the entire outer surface of the first spacer 421. The second spacer 422 contacts the upper surface of the substrate 101. The lower surface of the second spacer 422 may contact the impurity area 104 in the substrate 101. In an embodiment, the lower surface of the second spacer 422 may be positioned lower than the lower surface of the first spacer 421. The second spacer 422 may include silicon nitride, silicon carbide, silicon oxide, or a combination thereof. In an embodiment, the second spacer 422 may include silicon oxide.

The third spacer 423 is disposed on the source/drain areas 105 and 106, the second spacer 422, and the gate structure 103. The third spacer 423 may cover the upper surface of the source/drain areas 105 and 106 in the substrate 101, the side surface and the upper surface of the second spacer 422, and the upper surface of the gate structure 103. An inner side surface of the third spacer 423 may contact the second spacer 422. The lower surface of the third spacer 423 may contact the source/drain areas 105 and 106 of the substrate 101. The third spacer 423 may include silicon nitride, silicon carbide, silicon oxide, or a combination thereof. In an embodiment, the third spacer 423 may be silicon nitride.

In an embodiment, the first spacer 421 may include a material having a dielectric constant less than that of the material forming the third spacer 423. For example, the first spacer 421 may include SiCO, SiCON, SiCOH, or a combination thereof.

In an embodiment, the first spacer 421 may include SiCO, SiCON, SiCOH, or a combination thereof, the second spacer 422 may include silicon oxide, and the third spacer 423 may include silicon nitride.

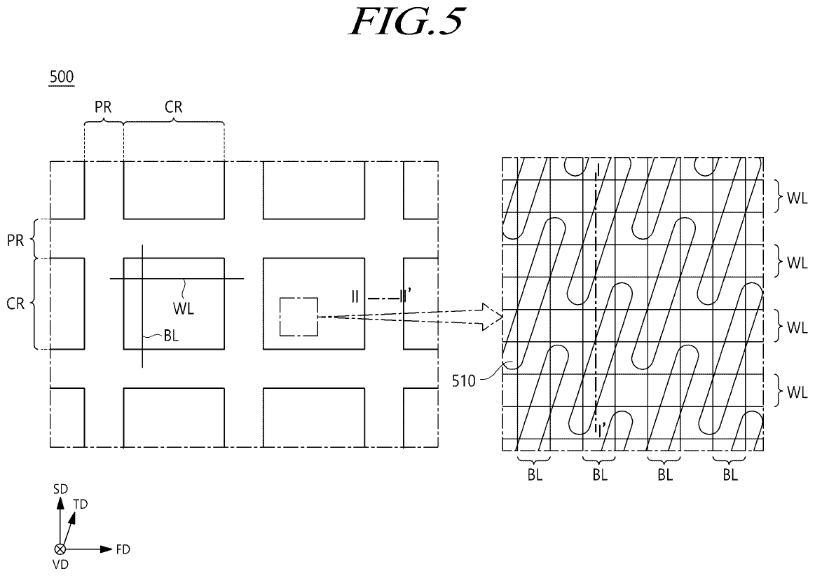

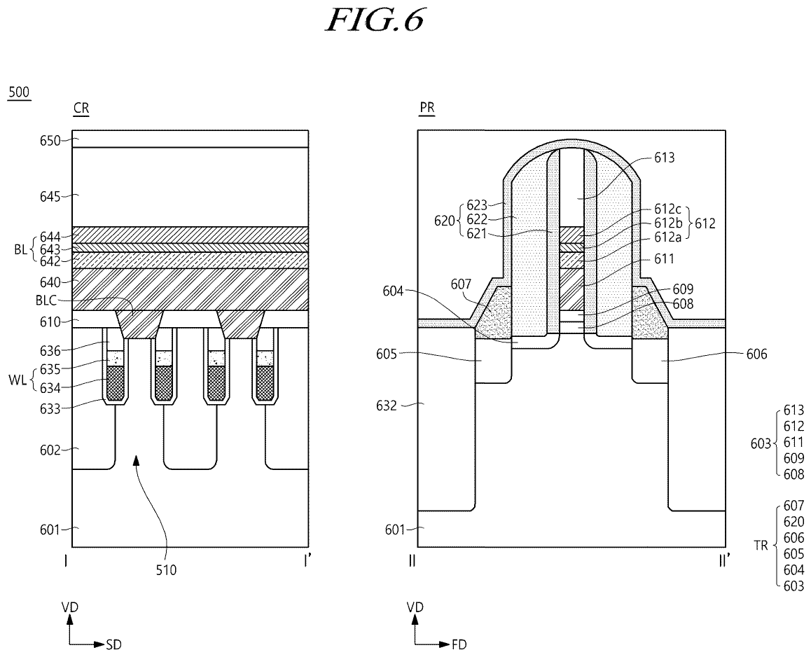

FIGS. 5 and 6 are views illustrating a semiconductor device according to embodiments of the present disclosure.

FIG. 5 is a view illustrating a planar structure of a semiconductor device 500 according to embodiments of the present disclosure. FIG. 6 is a view illustrating a cross-sectional structure of a semiconductor device 500 according to embodiments of the present disclosure.

In an embodiment, the semiconductor device 500 may be a memory device. The semiconductor device may be, e.g., dynamic random access memory (DRAM), double data rate synchronous dynamic random access memory (DDR SDRAM), low power double data rate4 (LPDDR4) SDRAM, graphics double data rate (GDDR) SDRAM, low power DDR (LPDDR), Rambus dynamic random access memory (RDRAM), NAND flash memory, 3D NAND flash memory, NOR flash memory, resistive random access memory (RRAM), phase-change memory (PRAM), magnetoresistive random access memory (MRAM), ferroelectric random access memory (FRAM), or spin transfer torque random access memory (STT-RAM). However, the semiconductor device 500 is not necessarily limited to a memory device. That is, the semiconductor device 500 may be a non-memory device.

However, hereinafter, for convenience of description, a case where the semiconductor device 500 is a memory device, e.g., DRAM, is described.

Referring to FIG. 5, a semiconductor device 500 includes a cell area CR and a peripheral area PR. The cell area CR is the area in which a memory cell array is disposed. The peripheral area PR is an area in which peripheral circuits for transferring various voltages or signals to memory cells disposed in the cell area CR are disposed. The peripheral area PR is disposed around the cell area CR. In an embodiment, the peripheral area PR may surround the cell area CR.

The semiconductor device 500 includes a bit line BL, a word line WL, and an active area 510.

The active areas 510 are spaced apart from each other in the first direction FD and the second direction SD. The active area 510 extends along the third direction TD. The bit lines BL and the word lines WL are disposed to cross the active area 510. The bit line BL extends in the second direction SD. The word line WL extends in the first direction FD. The bit line BL and the word line WL are disposed to overlap the cell area CR.

Although FIG. 5 illustrates one bit line BL and one word line WL disposed in one cell area CR, the embodiments are not limited thereto. For example, the numbers of bit lines BL and word lines WL disposed in the cell area CR may be greater than those illustrated. Further, the bit line BL and the word line WL may be disposed in all cell areas CR.

Referring to FIG. 6, a semiconductor device 500 includes a substrate 601, element isolation layers 602 and 632, a cell gate insulation layer 633, a word line WL, a word line capping layer 636, an insulation layer 610, a bit line contact BLC, a conductive layer 640, a bit line BL, a bit line capping layer 645, a first transistor TR, and a buried insulation layer 650.

In the cell area CR, the element isolation layer 602 limiting the active area 510 is disposed in the substrate 601. The substrate 601 may include a semiconductor substrate such as a silicon wafer or a silicon on insulator (SOI) wafer. The substrate 601 may include a group III-V semiconductor substrate, e.g., a compound semiconductor substrate such as gallium arsenide (GaAs). The substrate 601 may include monocrystalline silicon, polysilicon, amorphous silicon, monocrystalline silicon germanium, polycrystalline silicon germanium, carbon-doped silicon, or a combination thereof. In an embodiment, the substrate 601 may be silicon doped with a group III element.

The word line WL is buried in the active area 510 of the substrate 601. The word line WL may be referred to as a buried word line or a buried gate. The word line WL includes a first word line 634 and a second word line 635. A word line capping layer 636 is disposed on the word line WL. A cell gate insulation layer 633 is disposed between the word line WL and the substrate 601. The cell gate insulation layer 633 is also disposed between the word line capping layer 636 and the substrate 601. The cell gate insulation layer 633 surrounds the side surface and the lower surface of the word line WL. The word line WL may include a conductive material such as metal, metal nitride, metal silicide, polysilicon, conductive carbon, or a combination thereof. The cell gate insulation layer 633 may include silicon oxide, silicon nitride, silicon oxynitride, high-K dielectric, or a combination thereof. The word line capping layer 636 may include silicon nitride.

The insulation layer 610 is disposed on the substrate 601. The insulation layer 610 may be a single layer or multiple layers. The insulation layer 610 may include silicon oxide or silicon nitride.

The bit line contact BLC passes through the insulation layer 610 and contacts the active area 510 of the substrate 601. The lower surface of the bit line contact BLC may be positioned lower than the upper surface of the substrate 601. In an embodiment, two word lines WLs may be positioned between the two bit line contacts BLC in the second direction SD. In an embodiment, the bit line contact BLC may include the same material as the material forming the first gate electrode 611.

The conductive layer 640, the bit line BL, and the bit line capping layer 645 are sequentially disposed on the bit line contact BLC in the vertical direction. The conductive layer 640 is disposed on the bit line contact BLC. In an embodiment, the conductive layer 640 may include the same material as the material forming the bit line contact BLC.

The bit line BL is disposed on the conductive layer 640. The bit line BL includes a first bit line 642, a second bit line 643, and a third bit line 644. In an embodiment, the first bit line 642 and the second bit line 643 may include the same material as the material forming the barrier layers 612a and 612b, respectively. In an embodiment, the third bit line 644 may include the same material as the material forming the electrode layer 612c.

The bit line capping layer 645 is disposed on the bit line BL. In an embodiment, the bit line capping layer 645 may include the same material as the material forming the gate capping layer 613. The buried insulation layer 650 may be disposed on the bit line capping layer 645.

In the peripheral area PR, the first transistor TR includes a gate structure 603, an impurity area 604, source/drain areas 605 and 606, and spacers 620. The first transistor TR may be one transistor included in a peripheral circuit. In an embodiment, the first transistor TR may be one transistor included in a sub word line driver or a sense amplifier. Hereinafter, the first transistor TR may be referred to as a peripheral transistor TR.

The gate structure 603, the impurity area 604, the source/drain areas 605 and 606, and the spacers 620 may be substantially the same as the gate structure 103, the impurity area 104, the source/drain areas 105 and 106, and the spacers 120, respectively, of the semiconductor device 100 described with reference to FIG. 1.

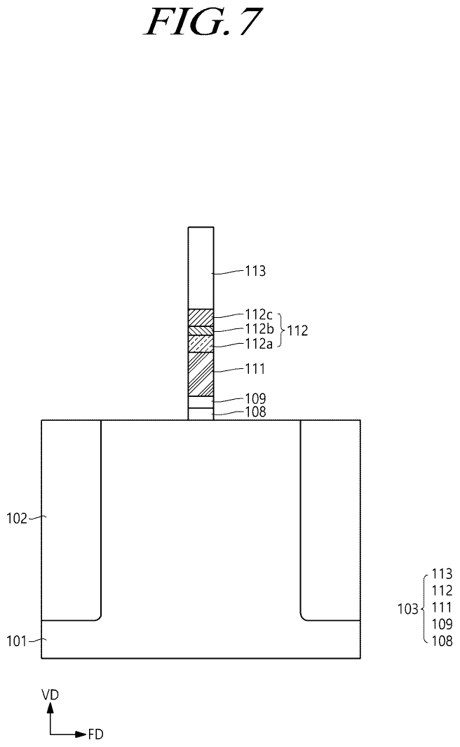

FIGS. 7 to 15 are views illustrating a method for manufacturing a transistor included in a semiconductor device according to embodiments of the present disclosure.

Referring to FIG. 7, at least one element isolation layer 102 is formed in the substrate 101. The gate structure 103 is formed on the substrate 101 between the element isolation layers 102. The gate structure 103 may have the structure in which the gate insulation layer 108, the work function adjustment layer 109, the first gate electrode 111, the second gate electrode 112, and the gate capping layer 113 are sequentially stacked. In an embodiment, the second gate electrode 112 may be formed in a structure in which barrier layers 112a and 112b and the electrode layer 112c are sequentially stacked. The process of forming the gate structure 103 on the substrate 101 may include an etching process. A width of the gate structure 103 in the first direction FD may be formed through the etching process.

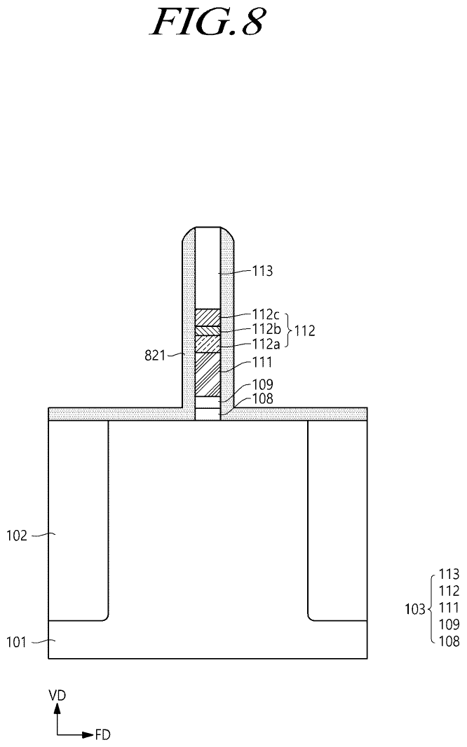

Referring to FIG. 8, the first insulation layer 821 is formed on side surfaces of the gate structure 103 and also on the exposed top surface of the substrate 101. In an embodiment, the first insulation layer 821 may conformally cover the upper surface of the substrate 101 and the side surface of the gate structure 103. In an embodiment, the first insulation layer 821 may include silicon nitride. In another embodiment, the first insulation layer 821 may include SiCO, SiCON, SiCOH, or a combination thereof.

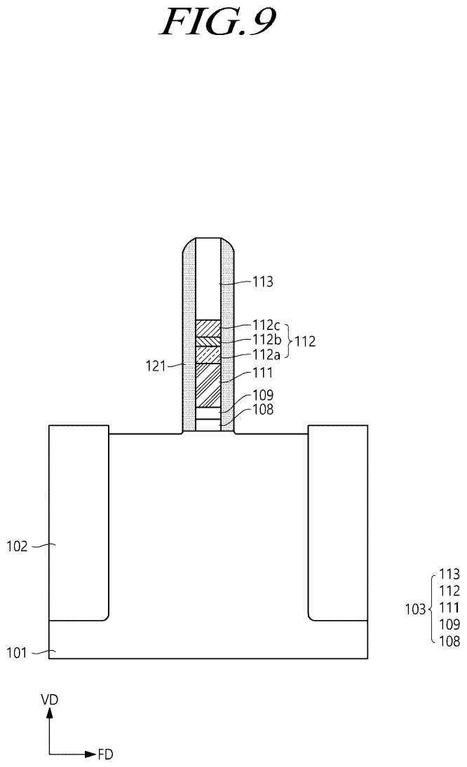

Referring to FIG. 9, a portion of the first insulation layer 821 is removed to form the first spacer 121. The process of removing the first insulation layer 821 may include an etching process. In the process of removing a portion of the first insulation layer 821, a portion of the substrate 101 may also be removed. In an embodiment, at least a portion of the upper surface of the substrate 101 adjacent to the gate structure 103 may be positioned lower than the upper surface of the substrate 101 overlapping the gate structure 103.

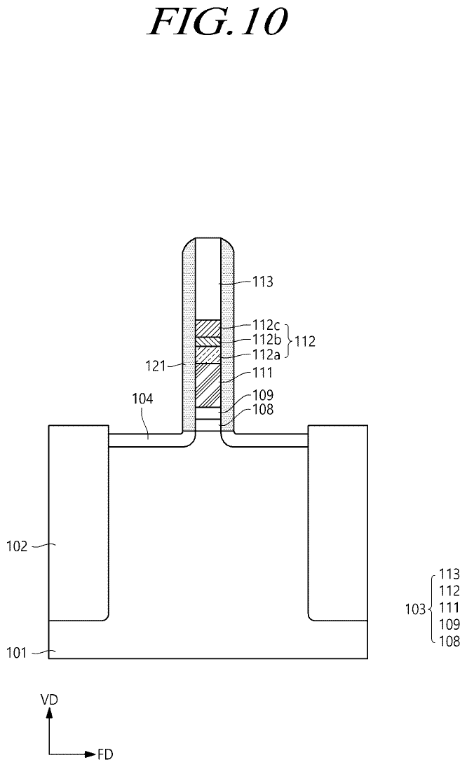

Referring to FIG. 10, the impurity area 104 is formed on the upper portion of the substrate 101 that is adjacent to the gate structure 103. The impurity area 104 may be an area in which the impurity concentration is higher than the impurity concentration included in the substrate 101. The impurity area 104 may include a lightly doped drain (LDD) area and a halo doped area. The process of forming the impurity area 104 may include a doping process such as an ion implantation process.

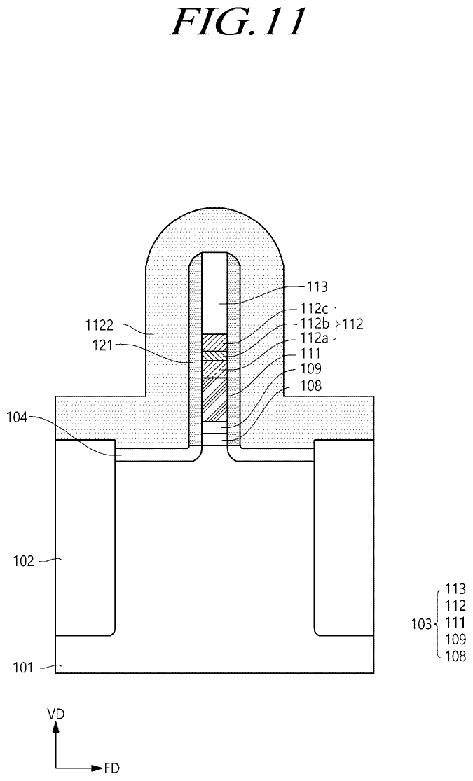

Referring to FIG. 11, a second insulation layer 1122 is formed on the substrate 101, the first spacer 121, and the gate structure 103. In an embodiment, the second insulation layer 1122 may conformally cover the upper surface of the impurity area 104 of the substrate 101, the side surface and upper surface of the first spacer 121, and the upper surface of the gate structure 103. In an embodiment, the second insulation layer 1122 may include SiCO, SiCON, SiCOH, or a combination thereof. In another embodiment, the second insulation layer 1122 may include silicon oxide.

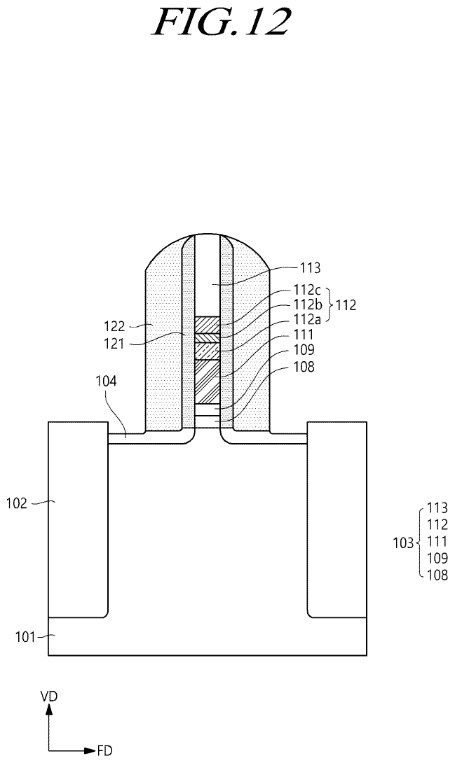

Referring to FIG. 12, a portion of the second insulation layer 1122 is removed to form the second spacer 122. The process of removing the second insulation layer 1122 may include an etching process. In the process of removing a portion of the second insulation layer 1122, a portion of the substrate 101 may also be removed. In an embodiment, at least a portion of the upper surface of the substrate 101 adjacent to the second spacer 122 may be positioned lower than the upper surface of the substrate 101 overlapping the second spacer 122.

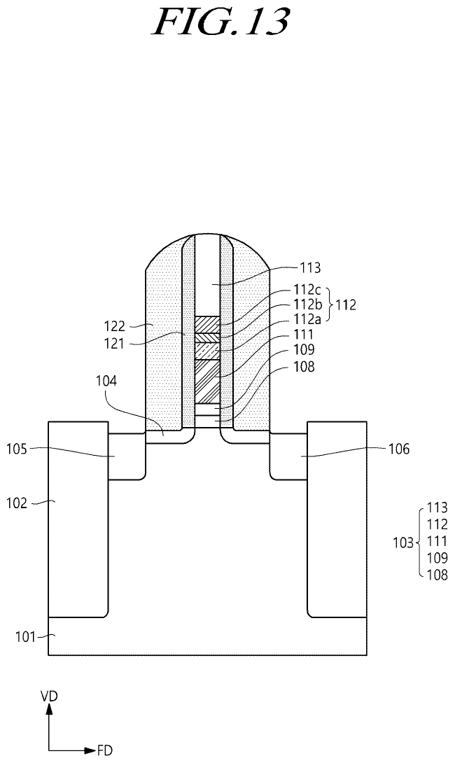

Referring to FIG. 13, the source/drain areas 105 and 106 are formed on an upper portion of the substrate 101 adjacent to the second spacer 122. The process of forming the source/drain areas 105 and 106 may include a doping process such as ion implantation. In an embodiment, the source/drain areas 105 and 106 may be formed by doping with N-type impurities. The N-type impurities may include P, As, or a combination thereof. The source/drain areas 105 and 106 may be formed adjacent to the impurity area 104. The source/drain areas 105 and 106 may extend deeper in the substrate 101 than the impurity area 104.

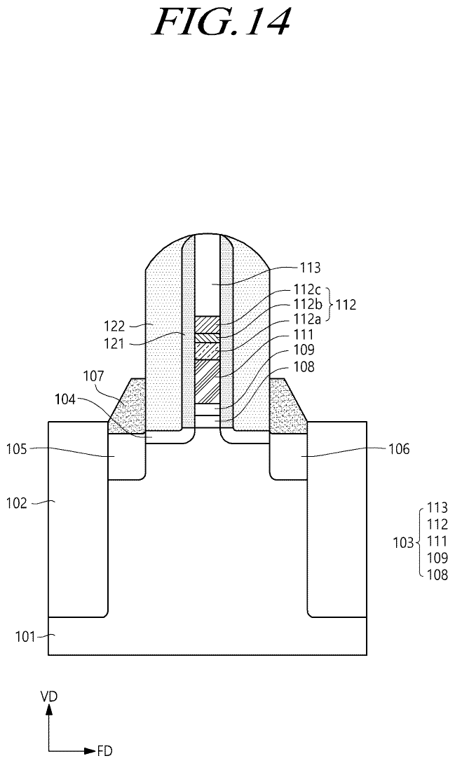

Referring to FIG. 14, the semiconductor layer 107 is formed on the source/drain areas 105 and 106. Before the semiconductor layer 107 is formed, a cleaning process (e.g., a wet etching process) for removing the oxide layer may be performed. The oxide layer formed on the upper surfaces of the source/drain areas 105 and 106 may be removed through the cleaning process.

The semiconductor layer 107 may be formed by a method such as selective epitaxial growth (SEG). The semiconductor layer 107 may be a material layer capable of enhancing carrier mobility. In an embodiment, the semiconductor layer 107 may include silicon germanium. The upper surface of the semiconductor layer 107 may be positioned higher than the upper surface of the substrate 101.

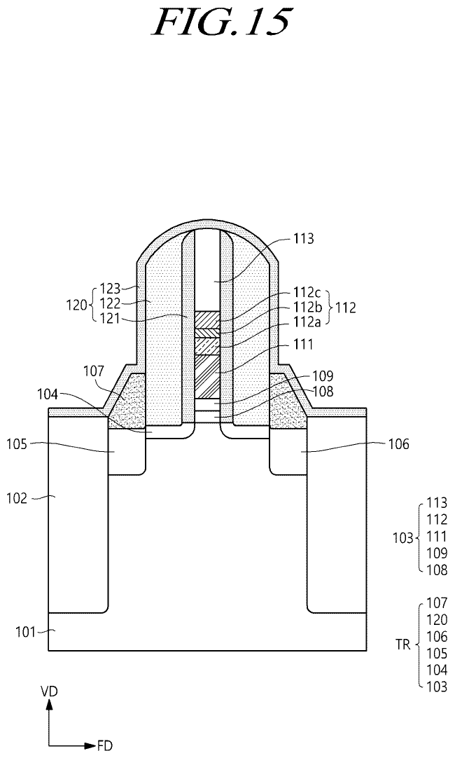

Referring to FIG. 15, the third spacer 123 is formed on the semiconductor layer 107, the second spacer 122, and the gate structure 103. The third spacer 123 may contact the upper surface of the gate structure 103. In an embodiment, the third spacer 123 may include silicon nitride.

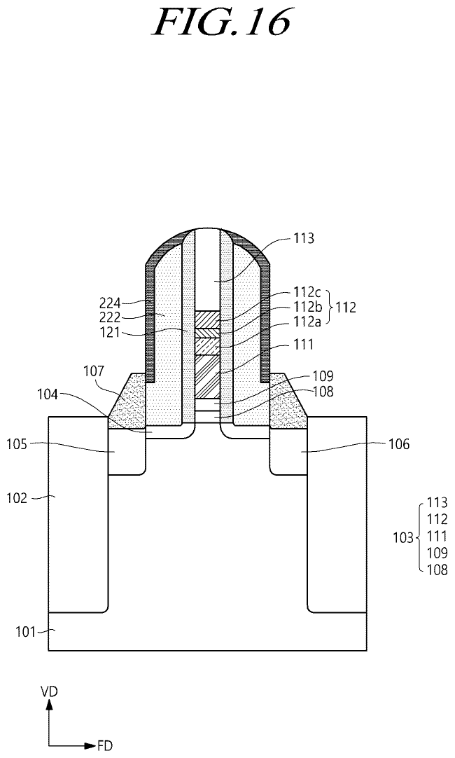

FIGS. 16 to 21 are views illustrating another method for manufacturing a transistor included in a semiconductor device according to embodiments of the present disclosure.

The semiconductor device illustrated in FIG. 16 may be formed in substantially the same manner as the method for manufacturing the semiconductor device described with reference to FIGS. 7 to 14.

Referring to FIG. 16, the fourth spacer 224 is formed on the outer surface of the second spacer 222. The fourth spacer 224 may be a layer formed by partially oxidizing upper and side portions of the second spacer 122 of the semiconductor device shown in FIG. 14. The fourth spacer 224 may include an oxide. In an embodiment, the fourth spacer 224 may be silicon oxide. At least a portion of the outer surface of the fourth spacer 224 may contact the semiconductor layer 107. The lower surface of the fourth spacer 224 may be spaced apart from the upper surface of the substrate 101 in the vertical direction. The lower surface of the fourth spacer 224 may be positioned lower than the upper surface of the semiconductor layer 107 so that an upper portion of the inner surface of the semiconductor layer 107 may contact an outer surface of the lower portion of the fourth spacer that is below the top surface of the semiconductor layer 107.

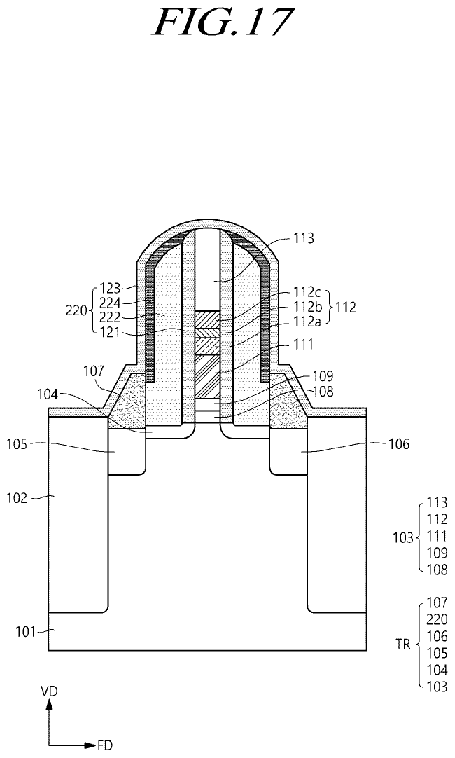

Referring to FIGS. 2 and 17, the third spacer 123 is formed on the semiconductor layer 107, the fourth spacer 224, and the gate structure 103. The third spacer 123 may be spaced apart from the second spacer 222. The inner surface of the third spacer 123 may not contact the second spacer 222. Stated differently, the third spacer 123 may be separated from the second spacer 222 by the fourth spacer 224. In an embodiment, the third spacer 123 may include silicon nitride.

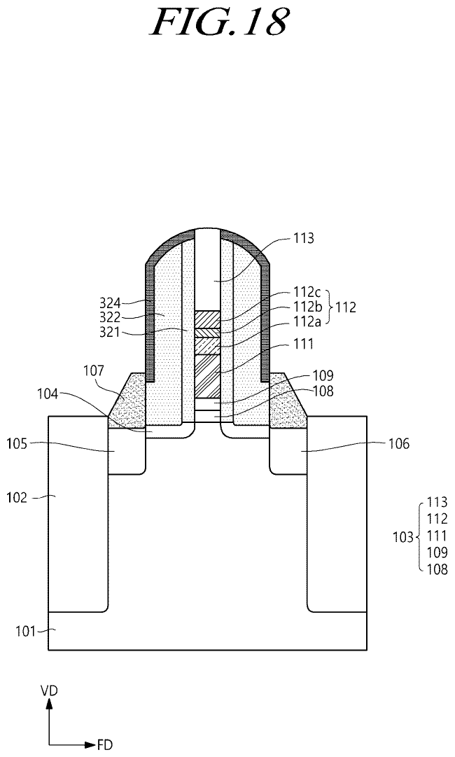

Referring to FIG. 18, the first spacer 321 may include a material different from the material forming the first spacer 121 included in the semiconductor device described with reference to FIGS. 7 to 14. In an embodiment, the first spacer 321 may include SiCO, SiCON, SiCOH, or a combination thereof. The first spacer 321 illustrated in FIG. 18 may be formed in substantially the same manner as the method of forming the first spacer 121 described with reference to FIGS. 8 and 9.

The impurity area 104, the source/drain areas 105 and 106, the second spacer 322, and the semiconductor layer 107 may be formed in substantially the same manner as the method for manufacturing the semiconductor device described with reference to FIGS. 10 to 14.

The fourth spacer 324 is formed on the outer surface of the second spacer 322. The fourth spacer 324 may be a layer formed by partially oxidizing the upper portion of the first spacer 321 and the upper portion and the side portion of the second spacer 322. The fourth spacer 324 may include oxide. In an embodiment, the fourth spacer 324 may be silicon oxide.

The fourth spacer 324 may contact the side surface of the gate capping layer 113 included in the gate structure 103. At least a portion of the outer surface of the fourth spacer 324 may contact the semiconductor layer 107. The lower surface of the fourth spacer 324 may be spaced apart from the upper surface of the substrate 101 in the vertical direction. The lower surface of the fourth spacer 324 may be positioned lower than the upper surface of the semiconductor layer 107.

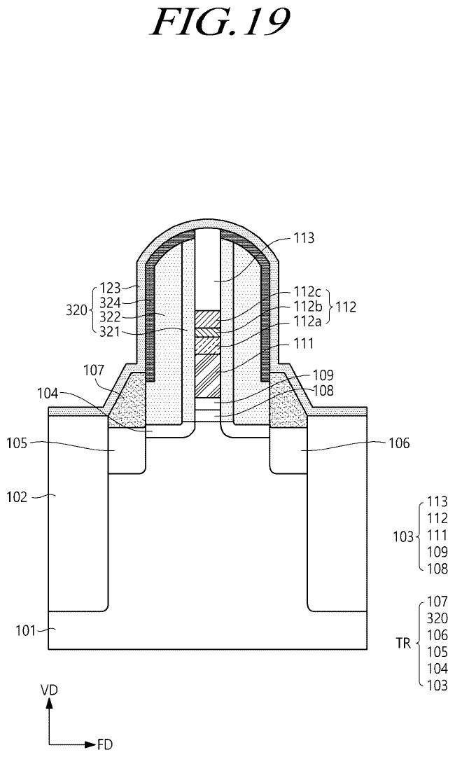

Referring to FIGS. 3 and 19, the third spacer 123 is formed on the semiconductor layer 107, the fourth spacer 324, and the gate structure 103. The third spacer 123 may be spaced apart from the first spacer 321 and the second spacer 322. The third spacer 123 may not contact the upper surface of the first spacer 321 and the upper surface of the second spacer 322. In an embodiment, the third spacer 123 may include silicon nitride.

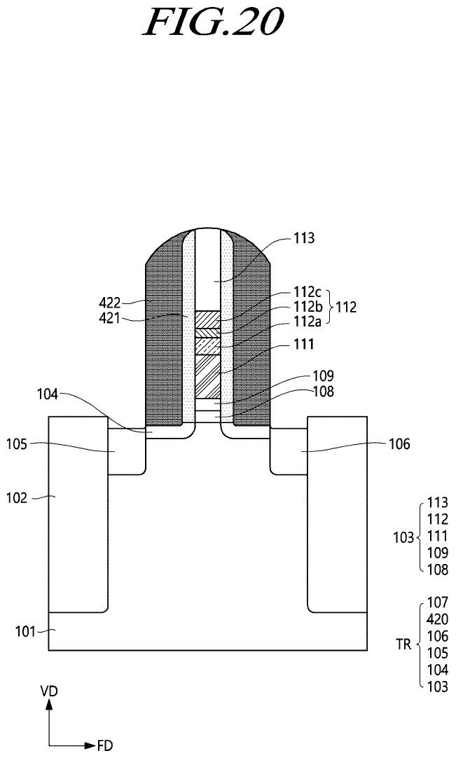

Referring to FIG. 20, the first spacer 421 may include a material different from the material forming the first spacer 121 included in the semiconductor device described with reference to FIGS. 7 to 14. In an embodiment, the first spacer 421 may include SiCO, SiCON, SiCOH, or a combination thereof. The first spacer 421 illustrated in FIG. 20 may be formed in substantially the same manner as the method of forming the first spacer 121 described with reference to FIGS. 8 and 9.

The second spacer 422 may include a material different from the material forming the second spacer 122 included in the semiconductor device described with reference to FIGS. 7 to 14. In an embodiment, the second spacer 422 may include silicon oxide. The second spacer 422 may be formed in substantially the same manner as the method of forming the second spacer 122 described with reference to FIGS. 11 and 12.

The impurity area 104 and the source/drain areas 105 and 106 may be formed in substantially the same method as the method for manufacturing the semiconductor device described with reference to FIGS. 10 and 13.

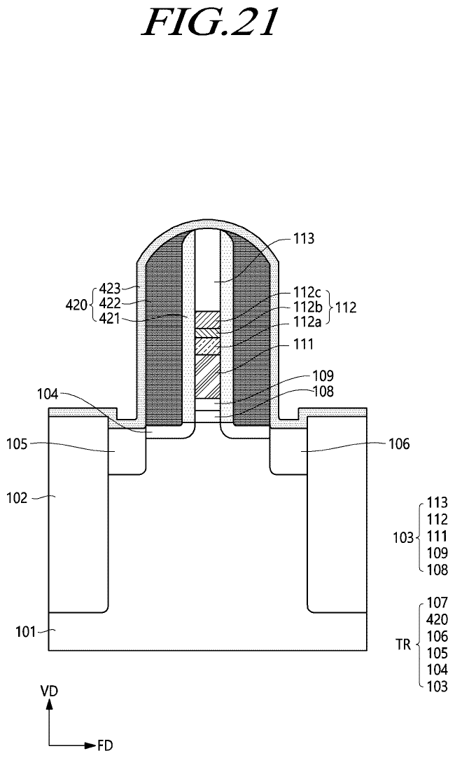

Referring to FIGS. 4 and 21, the third spacer 423 is formed on the source/drain areas 105 and 106, the second spacer 422 and the gate structure 103. The third spacer 423 may contact the side surface and the upper surface of the second spacer 422. The third spacer 423 may contact the source/drain areas 105 and 106 of the substrate 101. The third spacer 423 may include a material different from the material forming the first spacer 421. In an embodiment, the third spacer 423 may include silicon nitride.

Referring back to FIGS. 1 and 14, a semiconductor device 100 according to an embodiment of the present disclosure includes a semiconductor layer 107, a first spacer 121, a second spacer 122, and a third spacer 123. The second spacer 122 may include SiCO, SiCON, SiCOH, or a combination thereof.

According to embodiments of the present disclosure, a cleaning process such as a wet etching process may be performed to remove the oxide layer formed on the source/drain areas 105 and 106 after the second spacer 122 is formed and before the semiconductor layer 107 is formed. As the second spacer 122 includes SiCO, SiCON, SiCOH, or a combination thereof, the second spacer 122 may be prevented from being etched out together when the cleaning process is performed. Further, as the second spacer 122 includes a material with a relatively low dielectric constant compared to silicon nitride, parasitic capacitance generated around the gate electrode structure 103 may be reduced compared to when a material with a high dielectric constant such as silicon nitride is used as the second spacer 122.

Referring back to FIGS. 2, 3, 16, and 18, the semiconductor device 100 according to an embodiment of the present disclosure includes a fourth spacer 224 or 324. The fourth spacer 224 or 324 may be a layer generated by partially oxidizing the second spacer 222 or 322. The fourth spacer 224 or 324 may include silicon oxide.

According to embodiments of the present disclosure, as the fourth spacer 224 or 324 includes a material having a dielectric constant lower than that of SiCO, SiCON, SiCOH, or a combination thereof, parasitic capacitance may be further reduced compared to when only the second spacer 222 or 322 is disposed on the side surface of the gate structure 103.

Therefore, the semiconductor device according to embodiments of the present disclosure may prevent the parasitic capacitance from increasing in the element due to a process defect, thereby preventing deterioration of element characteristics.

The above-described embodiments are merely examples, and it will be appreciated by one of ordinary skill in the art various changes may be made thereto without departing from the scope of the present disclosure. Accordingly, the embodiments set forth herein are provided for illustrative purposes, but not to limit the scope of the present disclosure, and should be appreciated that the scope of the present disclosure is not limited by the embodiments. The scope of the present disclosure should be construed by the following claims, and all technical details within equivalents thereof should be interpreted to belong to the scope of the present disclosure. Furthermore, the embodiments may be combined to form additional embodiments.

What is claimed is:

1. A semiconductor device comprising:
a gate structure disposed on a substrate;
a first spacer disposed on the substrate and disposed on two opposite sides of the gate structure;
a second spacer disposed on the substrate, outside the first spacer, and including SiCO, SiCON, SiCOH, or a combination thereof;
a semiconductor layer disposed on the substrate and contacting an outer surface of the second spacer; and
a third spacer covering an upper surface of the gate structure, a side surface of the second spacer, and an upper surface of the semiconductor layer.

2. The semiconductor device of claim 1, wherein the first spacer includes a material having a dielectric constant greater than that of a material forming the second spacer.

3. The semiconductor device of claim 2, wherein the first spacer includes silicon nitride.

4. The semiconductor device of claim 1, wherein the first spacer includes the same material as a material forming the second spacer.

5. The semiconductor device of claim 1, further comprising a fourth spacer disposed between the second spacer and the third spacer.

6. The semiconductor device of claim 5, wherein the fourth spacer contacts a side surface of the semiconductor layer and is spaced apart from an upper surface of the substrate.

7. The semiconductor device of claim 5, wherein the fourth spacer includes a material having a dielectric constant less than that of a material forming the second spacer.

8. The semiconductor device of claim 7, wherein the fourth spacer includes silicon oxide.

9. The semiconductor device of claim 1, wherein the semiconductor layer is an epitaxial layer.

10. A semiconductor device comprising:
a substrate including a cell area and a peripheral area around the cell area; and
a peripheral transistor disposed in a peripheral area of the substrate, wherein the peripheral transistor includes:
a gate structure disposed on the substrate;
a plurality of spacers disposed on the substrate, positioned on a side surface of the gate structure, and at least partially including SiCO, SiCON, SiCOH, or a combination thereof; and
a semiconductor layer disposed on the substrate and spaced apart from the gate structure in a direction parallel to an upper surface of the substrate.

11. The semiconductor device of claim 10, wherein the plurality of spacers further includes a first spacer contacting a side surface of the gate structure and a second spacer disposed outside the first spacer, and
wherein the second spacer includes SiCO, SiCON, SiCOH, or a combination thereof.

12. The semiconductor device of claim 11, wherein the first spacer includes SiCO, SiCON, SiCOH, or a combination thereof.

13. The semiconductor device of claim 10, wherein the plurality of spacers further includes a first spacer contacting a side surface of the gate structure, a second spacer disposed outside the first spacer, a third spacer disposed outside the second spacer, and a fourth spacer disposed between the second spacer and the third spacer, and
wherein the fourth spacer contacts a side surface of the semiconductor layer and is spaced apart from an upper surface of the substrate.

14. A semiconductor device comprising:
a gate structure disposed on a substrate and spacers covering the sides and top surface of the gate structure;
wherein the spacers comprise first, second, third, and fourth spacers,
wherein the first and second spacers are disposed on the substrate and on two opposite sides of the gate structure,
wherein the third spacer is disposed on a side surface of the second spacer and also over top surfaces of the first and second spacers and the top surface of the gate structure, and
wherein the fourth spacer is disposed between the second and third spacer and does not contact the substrate.

15. The semiconductor device of claim 14, further comprising a semiconductor layer disposed on a source area and a drain area of the substrate.

16. The semiconductor device of claim 15, wherein the fourth spacer is disposed between the semiconductor layer and the second spacer.

17. The semiconductor device of claim 16, wherein the fourth spacer is spaced apart from an upper surface of the substrate.

18. The semiconductor device of claim 16, wherein the fourth spacer includes a material having a dielectric constant less than that of a material forming the second spacer.

19. The semiconductor device of claim 18, wherein the fourth spacer includes silicon oxide.

20. The semiconductor device of claim 14, wherein the second spacer includes SiCO, SiCON, SiCOH, or a combination thereof.
